(19) United States
(12) Patent Application Publication
(10) Pub. No.: US 2013/0154887 A1
(43) Pub. Date: Jun. 20, 2013

(54) ANTENNA TESTING ENCLOSURES AND METHODS FOR TESTING ANTENNA SYSTEMS THEREWITH

(71) Applicants: Paul W. Hein, McKinney, TX (US); Edward K. Lule, McKinney, TX (US); James L. Pitts, JR., Greenville, TX (US); Dennis M. Fox, Rockwall, TX (US)

(72) Inventors: Paul W. Hein, McKinney, TX (US); Edward K. Lule, McKinney, TX (US); James L. Pitts, JR., Greenville, TX (US); Dennis M. Fox, Rockwall, TX (US)

(21) Appl. No.: 13/327,314

(22) Filed: Dec. 15, 2011

(51) Int. Cl. G01R 29/08

(52) U.S. Cl. 343/703

(57) ABSTRACT

Antenna enclosure apparatus are provided that may be used to verify the signal path integrity, amplitude and/or phase of a single antenna or multiple antennas of direction finding (DF) antenna array and associated electronics without interference of external signals such as ground interference signals present when an aircraft-based antenna is tested on the ground. An individual antenna test enclosure may in one embodiment be provided as an antenna hood having a cavity dimensioned for internally receiving an antenna, such as an aircraft external blade antenna. The cavity of the antenna enclosure may be lined with a RF absorbing material inside the enclosure to allow for RF path testing with substantially no “ringing”, so that accurate phase and gain testing of a received antenna and its RF signal path may be accomplished.

This invention was made with United States Government support under Contract No. FA8620-06-G-4003. The Government has certain rights in this invention.

### FIELD OF THE INVENTION

This invention relates generally to antennas, and more particularly to antenna testing enclosures and methods for testing antenna systems therewith.

### BACKGROUND

Aircraft are provided with external antennas for a number of applications. These antennas are coupled by a radio frequency (RF) signal path to receive or transmission circuitry within the aircraft. In the past, the RF signal receive path of such an aircraft have been tested on the ground by removing the antennas and injecting a test signal into the RF cables of the signal path. In other cases, a signal-radiating antenna element has been directly taped against the surface of an aircraft receive antenna for applying a test signal to the antenna and its signal path.

In yet other cases, antenna hoods have been employed to enclose and ground test external aircraft antennas. Such a conventional antenna hood is an unlined metal enclosure that is configured to cover an aircraft antenna to amplitude test the RF receive path of the individual antenna. The metal enclosure of the antenna hood acts to block RF energy. A separate strip or blade antenna is positioned within the enclosure on each of two opposing internal sides of the antenna hood such that the antenna is positioned in-between the two separate blade antennas when the antenna hood is placed over the aircraft antenna. Multiple such conventional metal antenna hoods have been simultaneously placed over multiple external antenna elements of an aircraft-based direction finding (DF) system for purposes of testing the phase relationship of the RF signal path between the antennas and receiver. Such conventional systems are limited to measuring phase differences of 10 degrees or more between the multiple antennas.

### SUMMARY OF THE INVENTION

Disclosed herein are antenna testing enclosures (e.g., antenna hoods) that may be employed to provide improved isolation from background ground radio noise and improved system testing accuracy that is not possible with conventional antenna testing hoods and systems. The disclosed testing enclosures may be advantageously employed to achieve cost savings by providing visibility to the RF signal path for troubleshooting and system checks that otherwise may only be accomplished in a pristine environment with substantially no background ground ambient noise and with substantially no reflections, e.g., such as the pristine RF environment existing during flight tests of aircraft-based antenna systems. In one exemplary embodiment, the disclosed testing enclosures may be implemented for ground testing one or more antennas and signal paths of an aircraft signal receiving system (e.g., for DF antenna systems) to identify hardware discrepancies without requiring the additional time and cost of an aircraft recalibration flight. Significant time savings over conventional methodology may be realized in one embodiment when using the disclosed testing enclosures for end to end precision RF path testing and for verifying one or more electrical properties such as amplitude/gain and phase of multiple antennas installed as an array on an aircraft such as an aircraft-based DF system.

Examples of applications for the disclosed testing enclosures include, but are not limited to, testing during development and initial deployment and installation of antenna systems, field testing of previously installed antenna systems as a part of periodic antenna system maintenance operations, verification of proper operation of antenna systems after they have been disturbed to facilitate repairs, etc. In one embodiment, improved visibility and system stability may be made possible with the disclosed antenna testing enclosures and testing systems thereof, allowing antenna systems (e.g., DF antenna array systems such as DF interferometer, other phased array antenna systems, traffic collision avoidance system “TCAS” antenna systems, GPS antenna systems, etc.) to be tested and stabilized prior to initial flight tests, and allowing troubleshooting of antenna systems more effectively in the event that failures occur. Such characteristics may be taken advantage of, for example, to allow for test flights of newly installed aircraft antenna arrays on an aircraft to roll directly into a calibration flight, providing significant schedule savings since antenna and RF signal path problems may be discovered prior to the initial flight and not afterwards.

In one exemplary embodiment, multiple antenna testing enclosures may be provided in the form of a RF test system of multiple individual antenna enclosures that are configured for installation over respective multiple individual antennas of an antenna array, such as an aircraft-mounted DF system antenna array. In such an embodiment, the disclosed antenna enclosure apparatus may be used to verify integrity of the RF signal path, amplitude and/or phase of the antennas of the array and the DF system electronics installed on the aircraft when the aircraft is parked on the ground. In this regard, the RF test system may be employed in one exemplary embodiment to allow simultaneous, substantially uniform amplitude and substantially equal phase injection of RF energy into each antenna in the DF system antenna array, to verify the complete RF path from each antenna to the DF receiver, to isolate and reduce interference with the test measurements from external AC and ground effects, and to provide a test environment required for precise measurements of the DF system and its antenna array. Advantageously, the disclosed RF test system and its multiple antenna disclosures may be so used to verify the amplitude and phase of a DF system installed on an aircraft without requiring expensive and time consuming flight testing operations.

An individual antenna test enclosure may in one embodiment be provided with a cavity dimensioned for internally receiving an antenna, such as an aircraft external blade antenna. The cavity of the antenna test enclosure may be lined with a RF absorbing material inside the enclosure to create an anechoic chamber that allows for RF path testing with substantially no “ringing” characteristics (i.e., bouncing of RF energy inside the enclosure) which may lead to inaccurate phase and amplitude measurements of the antenna under test, and with substantially no interference from signal noise from the environment external to the antenna test enclosure. In this way accurate phase and gain testing of a received antenna and its RF signal path may be accomplished using the disclosed apparatus and methods. Using this antenna enclosure configuration, injection of a substantially pristine RF test signal into the antenna element may be performed with substantially no ringing into multiple antennas. Each of the antenna testing hoods may be used as part of an RF test system of multiple antenna test hoods to simultaneously inject RF test signals into multiple antennas of an antenna array (e.g., such as a DF antenna array) and into the entire RF path of a DF antenna system with less than or equal to about 10 degrees of phase difference (alternatively with less than 10 degrees of phase difference, alternatively with less than or equal to about 5 degrees of phase difference, alternatively with less than or equal to about 3 degrees of phase difference, and alternatively with less than or equal to about 2 degrees of phase difference) between the individual antennas of the array, and in a substantially isolated environment. The antenna enclosures of this embodiment may also be used to provide data on antenna gain as well as array phase relationship, without ground interference.

In one exemplary embodiment, a RF test system may be configured with multiple antenna test enclosures for testing multiple antennas of a DF antenna array, and may include multiple amplitude and phase matched antenna enclosures configured to couple RF energy into each antenna of the antenna array when it is installed on an aircraft as part of DF system. In one example implementation, the RF test system of this embodiment may include an equal-way power divider and a set of phase matched antenna enclosures. The input of the power divider may be fed with either a test port output (e.g., test signal generator) or an antenna enclosure placed over the radiation built in test (BIT) antenna. Each antenna enclosure may be configured to provide both coupling to an individual antenna of the array under test and to isolate the external environment over the full bandwidth of the antenna under test (AUT).

In one respect, disclosed herein is a method for testing one or more radio frequency antennas. In one embodiment, the method may include: providing one or more antennas and a corresponding RF signal path coupled to each of the antennas; providing one or more antenna test enclosures, each of the antenna test enclosures corresponding to one of the antennas and being configured to receive one of the antennas when positioned therein, each of the antenna test enclosures including a RF feed configured to radiate a RF test signal, the RF feed being configured as a continuous feed structure that completely encircles the antenna in at least one plane when the antenna is positioned within the antenna test enclosure. The method may also include positioning each of the one or more antennas within a corresponding one of the one or more antenna test enclosures so that the continuous feed structure of the RF feed completely encircles the antenna in at least one plane; providing a RF test signal to each given one of the one or more antenna test enclosures to cause the RF feed of the given antenna test enclosures to radiate the RF test signal to a corresponding one of the one or more antennas; and measuring the response to the RF test signal provided to each of the one or more antenna antennas and the RF signal path corresponding to each of the one or more antennas.

In another respect, disclosed herein is a system for testing one or more radio frequency antennas and a corresponding RF signal path coupled to each of the antennas. In one embodiment, the system may include: one or more antenna test enclosures, each of the antenna test enclosures corresponding to one of the antennas and being configured to receive one of the antennas when positioned therein, each of the antenna test enclosures including a RF feed configured to radiate a RF test signal, the RF feed being configured as a continuous feed structure that completely encircles the antenna in at least one plane when the antenna is positioned within the antenna test enclosure; and test circuitry configured to provide a RF test signal to each given one of the one or more antenna test enclosures to cause the RF feed of the given antenna test enclosures to radiate the RF test signal to a corresponding one of the one or more antennas.

In another respect, disclosed herein is an antenna test enclosure configured to receive a radio frequency antenna when positioned therein. In one embodiment, the antenna test enclosure may include a RF feed configured to radiate a RF test signal, the RF feed being configured as a continuous feed structure that completely encircles the antenna in at least one plane when the antenna is positioned within the antenna test enclosure.

### BRIEF DESCRIPTION OF THE DRAWINGS

FIG. 1 illustrates multiple antenna test enclosures and RF test circuitry according to one exemplary embodiment.

FIG. 2 illustrates a simplified block diagram of multiple antenna test enclosures and RF test circuitry according to one exemplary embodiment.

FIG. 3A illustrates test data for one antenna that is obtained using RF test circuitry according to one exemplary embodiment.

FIG. 3B illustrates test data for two antennas that is obtained using RF test circuitry according to one exemplary embodiment.

FIG. 4 illustrates an exploded view of a blade antenna disposed in operational relationship to an antenna test enclosure according to one exemplary embodiment.

FIG. 5 illustrates a partial wide side cross-sectional view of an antenna test enclosure according to one exemplary embodiment.

FIG. 6 illustrates a partial narrow side cross-sectional view of an antenna test enclosure according to one exemplary embodiment.

FIG. 7 illustrates a top view of a antenna feed according to one exemplary embodiment.

FIG. 8 illustrates a view of section A-A of the exemplary embodiment of FIG. 7.

FIG. 9 illustrates a top view of a dielectric plate according to one exemplary embodiment.

### DESCRIPTION OF ILLUSTRATIVE EMBODIMENTS

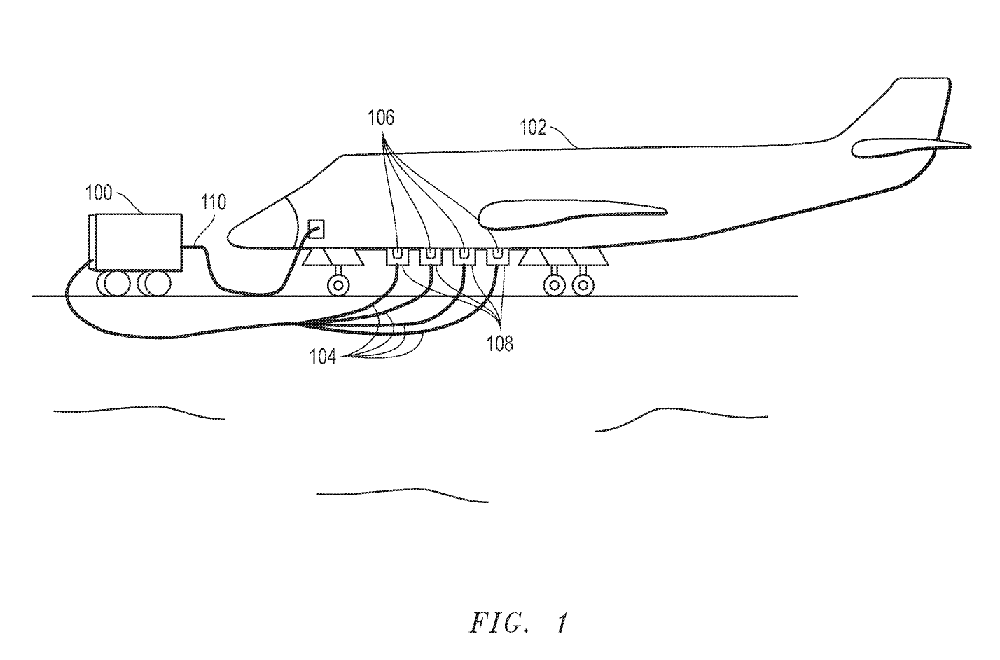

FIG. 1 illustrates an aircraft 102 (e.g., manned aircraft, unmanned drone, etc.) configured with a DF receiver system that includes an array of multiple external antennas 106 that are configured to receive and locate a radio frequency (RF) signal while aircraft 102 is airborne. In this embodiment, each of antennas 106 are blade antennas, such as a Dayton Granger DG 720032 or a Chelton Microwave 11D28500 blade antenna. However, it will be understood that the disclosed apparatus, systems and methods may be employed with other types of antennas and/or may be employed with single antennas rather than multiple antennas of an antenna array. Moreover, it will also be understood that the disclosed apparatus, systems and methods may be employed with one or more antennas mounted on or otherwise provided on mobile or stationary platforms other than a fixed wing aircraft, e.g., such as a helicopter, building, cell or other type of antenna tower, truck, ship, submarine, etc.

As shown in the illustrated embodiment of FIG. 1, aircraft 102 is parked on the ground and coupled to RF test circuitry 100 provided in this embodiment in a ground equipment cart. RF test circuitry 100 is configured for performing amplitude and/or phase ground testing of external antennas 106 and corresponding RF signal paths of a DF receiver system that includes circuitry installed or contained on aircraft 102. Also shown in FIG. 1 are multiple antenna test enclosures that are provided in the form of individual antenna hoods 108 that are installed over respective multiple antennas 106 of aircraft 102. Each of antenna enclosures 108 are coupled to the RF test circuitry of cart 100 by signal injection conductors (e.g., coaxial cables or other suitable signal conductors) 104 as shown, and RF test circuitry 100 is also shown coupled to DF receiver system circuitry (e.g., multi-channel, coherent tuners) within aircraft 102 by test signal return conductor (e.g., coaxial cables or other suitable signal conductors) 110.

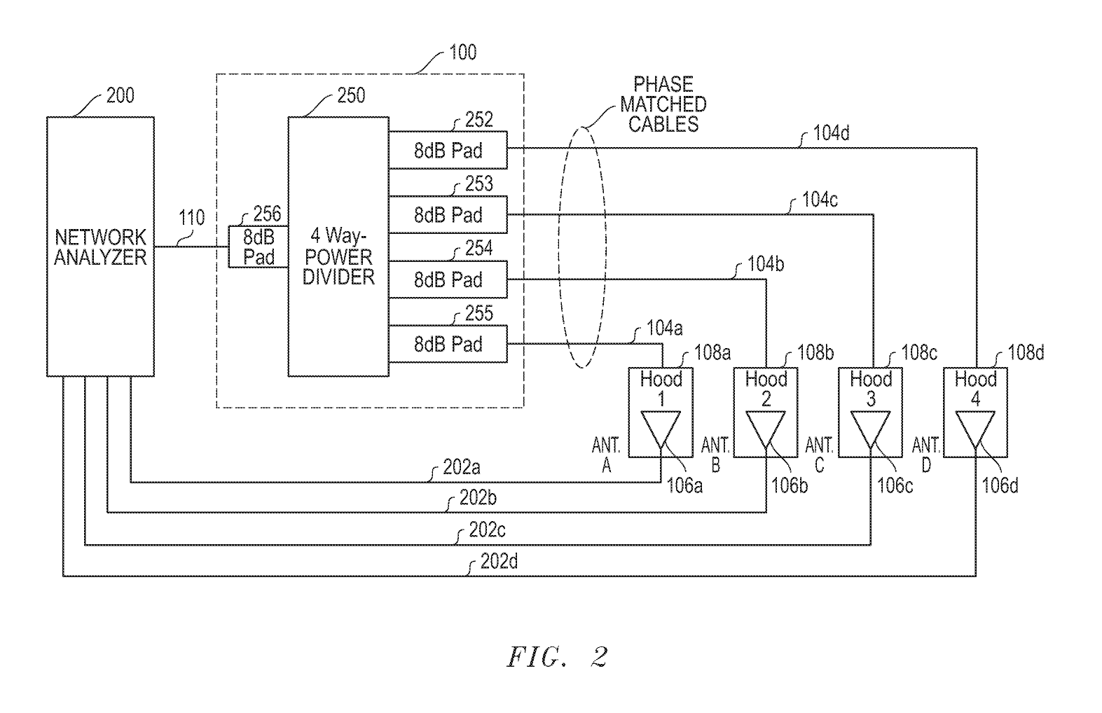

FIG. 2 illustrates one exemplary embodiment of RF test circuitry 100 as it may be configured and coupled for performing amplitude and/or phase ground testing of multiple external antennas 106a-106d and corresponding signal paths of a DF receiver system, such as that illustrated and described in relation to FIG. 1, it being understood that in other embodiments the number of antennas that may be tested may be more or less than four. In the embodiment of FIG. 2, RF text circuitry 100 includes 4-power divider 250 (e.g., Anzac DS-801, 2-2000 MHz 4-way Power Divider or other suitable power divider component) that is coupled via outputs 252, 253, 254 and 255 and signal injection conductors 104a, 104b, 104c and 104d to respective antenna enclosures 108a, 108b, 108c and 108d by respective phase matched signal injection coaxial cables 104a, 104b, 104c and 104d. Power divider 250 is also coupled to the second port of a network analyzer 200 by test signal return conductor 110 at input/output (common port) 256 as shown. Network analyzer 200 is also coupled to antennas 106a-106d by respective antenna output signal conductors 202a-202d as shown. Antenna enclosures 108a, 108b, 108c and 108d are positioned for testing over each of antennas 106a, 106b, 106c and 106d (e.g., 10-144050-1 UHF 150-500 MHz antennas or other antenna of suitable wavelength of a given application). Although power divider 250 is illustrated as being coupled to external circuitry via 8 dB pads, it will be understood that any other suitable interconnection circuitry or structure may be employed. Moreover, it will be understood that the particular configuration of RF test circuitry 100 of FIG. 2 is exemplary only, and that any other circuitry suitable for injecting or otherwise providing suitable RF test signals to antenna enclosures 108 may be employed.

During testing, power divider 250 may be employed to inject a RF test signal of a common phase simultaneously into each of the four antenna enclosures 108, i.e., such that each of antennas 106 simultaneously receives the same injected RF signal at the same phase. Response of the RF signal path coupled to each of antennas 106 may then be compared to the RF signal path coupled to each of the antennas 106 to verify that each of the four antennas 106 and its corresponding signal path simultaneously detects substantially the same injected signal phase at the same time as detected by each of the other antennas 106 and its corresponding signal path. Using this methodology, any offset error in detected phase between the different antennas 106 may be detected and corrected, e.g., by replacement or repair of the defective antenna 106 and/or its corresponding RF signal path. Absolute value of phase and/or amplitude detected by a given antenna 106 may also be compared to the phase and/or amplitude of an injected RF test signal of a given hood 108 to detect defects or measurement errors in a given antenna 106 and corresponding RF signal path. It will be understood that the above-described test methodologies are exemplary only, and that other test methodologies may be employed using one or more antenna enclosures 108.

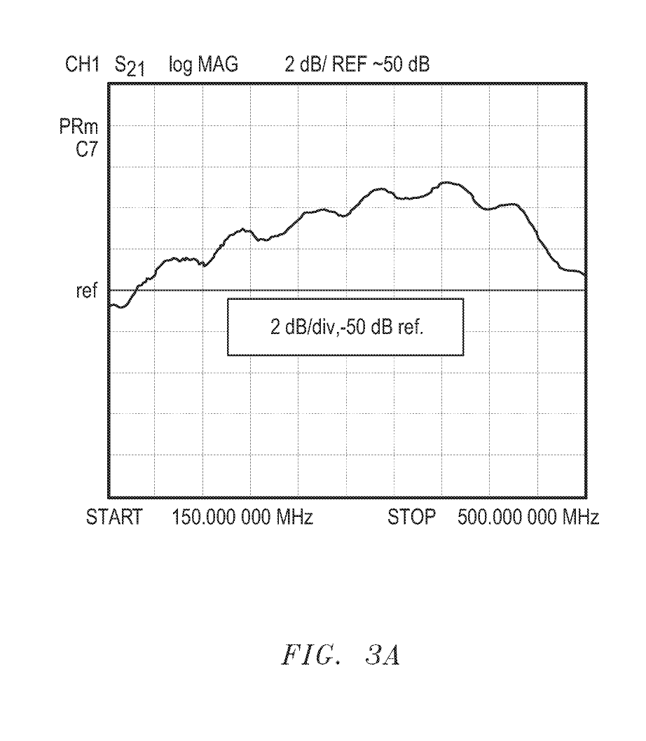

FIG. 3A illustrates test data for one antennas (e.g., such as antenna 106a of FIG. 2) that is obtained using RF test circuitry similar to that illustrated and described in relation to FIG. 2. In particular, FIG. 3A is a plot of coupling versus frequency obtained by feeding a continuous wave (CW) tone to one of the antenna enclosures 108 that is configured in a manner as described elsewhere herein, and that is operably positioned over a corresponding antenna 106 in a manner similar to that illustrated in FIG. 2. In the embodiment of FIG. 3A, the injected CW tone is swept from 150 MHz to 500 MHz to produce the response of FIG. 3A from the antenna 108 as shown. The data of FIG. 3A shows that feeding a signal to an antenna enclosure 108 successfully produces a substantially flat response from the antenna 106 positioned within the antenna enclosure 108.

FIG. 3B illustrates test data for two antennas (e.g., such as antennas 106a and 106b of FIG. 2) that is obtained using RF test circuitry similar to that illustrated and described in relation to FIG. 2. In particular, FIG. 3 is a plot of phase versus frequency obtained by simultaneously feeding a continuous wave (CW) tone to two antenna enclosures 108 that are each configured in a manner as described elsewhere herein, and that are each operably positioned over a corresponding antenna 106 in a manner similar to that illustrated in FIG. 2. In the embodiment of FIG. 3, the injected CW tone is swept from 150 MHz to 500 MHz to produce the response of FIG. 3 from the two antennas 108 as shown. The data of FIG. 3 shows that the two antenna enclosures 108 are phase matched, and that two respective antennas 106 are matched within a 10 degree window.

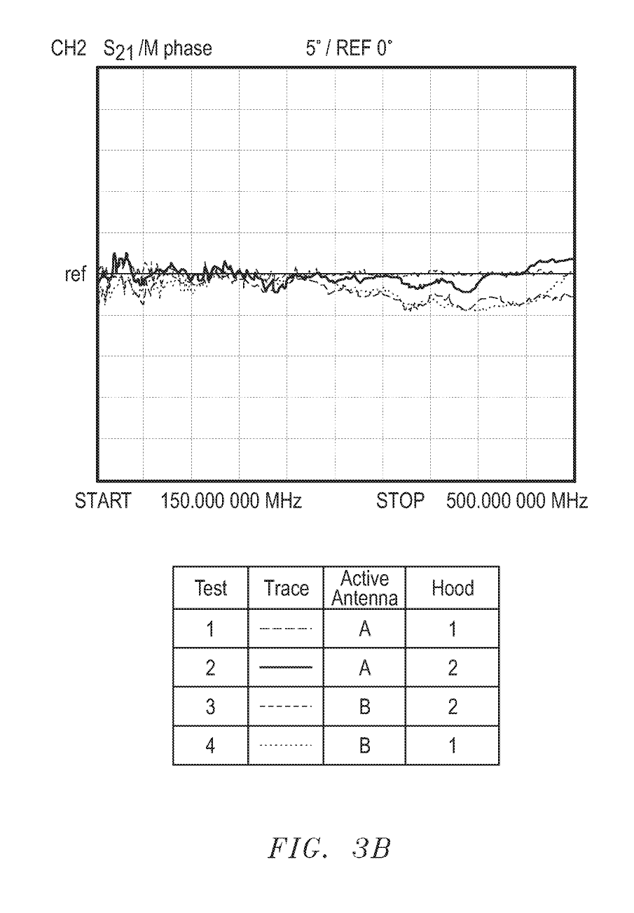

FIG. 4 illustrates an exploded view of a blade antenna 106 disposed in operational relationship to an antenna test enclosure 108 with an optional alignment plate device 410 disposed there between. Although antenna enclosure 108 may be positioned over a blade antenna 106 without alignment plate device 410, alignment plate device 410 may be provided in one exemplary embodiment to align antenna enclosure 108 over blade antenna 106 in a repeatable location for testing. This helps ensure acceptable phase repeatability, i.e., when antenna enclosure 108 is used in a phase matching measurement, it is typically desirable that its contribution to the measurement error should be minimal.

Alignment plate device 410 includes an antenna opening 420 defined therein that is dimensioned to fit over the exterior of blade antenna 106, and may be secured in relation to blade antenna 106, e.g., by countersunk screws 420 and 422 received through mounting holes 404 provided in the base 402 on the proximal end 442 of blade antenna 106. Vertically extending guide pins 412 of alignment plate device 410 may be configured and dimensioned to be received in corresponding vertical securing openings 430 defined in antenna enclosure 108 such that when antenna enclosure 108 is placed over blade antenna 106 as illustrated in FIG. 3, guide pins 412 may extend through antenna enclosure 108 and be secured to antenna enclosure 108, e.g., by threaded screws or other suitable fasteners 483 received in internally threaded openings within guide pins 412 as shown. It will be understood that more or less than four guide pins or other types (e.g., shape, length, etc.) of guide members may be alternatively employed.

Still referring to FIG. 4, antenna enclosure 108 is provided with an internal matrix 452 of RF absorbing material and is configured with an internal cavity 450 defined within matrix 452 that is shaped and dimensioned complementary to the exterior dimensions of blade antenna 106 such that antenna 106 is closely surrounded (e.g., by an exemplary space of about ⅛ inch clearance around the exterior of antenna 106 to provide a non-interference fit that does not interfere when inserting antenna 106 into cavity 450 or removing antenna 106 from cavity 450) on at least all sides in-between the proximal (base) end 442 and distal (tip) end 444 of the antenna 106 by the RF absorbing material matrix 452 or embedded RF feed 480 when the antenna 106 is positioned within the antenna test enclosure 108. Internal cavity 450 may extend through matrix 452 from an opening in a proximal insertion end 490 of antenna enclosure 108 and terminate within matrix 452 to form a closed-end cavity as shown, although it is alternatively possible that cavity 450 may extend completely through matrix 452 from proximal insertion end 490 of antenna enclosure 108 to a distal end 492 of antenna enclosure 108 such that a cavity opening is also defined in the surface of distal end 492 of hood 108. Such a distal opening may be covered with separate RF shielding material (e.g., metal shielding such as a metal plate) during RF testing operations when present.

In the illustrated embodiment, matrix 452 may be composed of any RF absorbing material that is suitable for effectively attenuating RF energy. Examples of suitable RF absorbing materials include, but are not limited to, C-RAM HC manufactured by Cuming Microwave Corp., etc. In one exemplary embodiment, a material exhibiting a RF absorption characteristic of 40 dB loss per inch of material (as measured at 10 GHz) may be employed. It will be understood that the embodiment of FIG. 3 is exemplary only, and that other shapes and configurations of antenna test enclosures may be provided for installation over other types and configurations of antennas, e.g., such as patch antenna, phased array antenna, antenna horns, etc. In one alternative embodiment, an antenna test enclosure 108 may be provided with a multi-piece (e.g., two-piece hinged or hingeless clam-shell) configuration that has opposing sides configured to be brought together to form a cavity 450 that around an antenna 106, rather than requiring insertion of the antenna 106 into the proximal end of a cavity 450. Such an alternative embodiment may be useful, for example, when testing an antenna 106 that has an irregular shape (e.g., circular shape, egg shape, bent shape, etc.) that is best closely surrounded by RF absorbing material of an antenna enclosure 108 that has multiple sides that are capable of being brought together around the body of the antenna 106 in close relationship to form a cavity that is complementary in shape and dimensions so as to closely receive the body of the antenna therein. In such an alternative embodiment, a multi-piece and mating embedded RF feed (embedded feeds are described in more detail further herein) may be provided that coupled together to form a continuous feed structure in at least one plane around the antenna 106 when the multiple sides of the enclosure 108 are assembled together around the antenna 106. Such a continuous feed structure may be so configured to radiate a RF test signal to antenna 106 in at least one plane from around the periphery of antenna 106.

Also shown in FIG. 4 is an antenna feed structure 480 that in this exemplary embodiment includes two parallel conductive (e.g., conductive metal such as copper, aluminum or other suitable conductive metal) plates 460 and 462 that are separated by a parallel dielectric plate 463 (e.g., dielectric material such as polytetrafluoroethylene (PTFE), low loss RF printed circuit board material, high density polyethylene (HDPE), etc. or other suitable dielectric material). As shown, components of antenna feed structure 480 are embedded between proximal and distal sections of RF absorbing material of matrix 452, and are oriented such that the parallel plates 460, 462, and 463 of antenna feed structure 480 are oriented in a plane that is perpendicular to the insertion direction of an antenna 106 into internal cavity 450 (i.e., the longitudinal axis 467 of internal cavity 450 lies perpendicular to (and intersects) the plane of components of antenna feed 480. As further shown, each of plates 460, 462 and 463 of antenna feed 480 has an antenna opening in the form of a slot defined therein that corresponds to and is aligned with an antenna opening defined in matrix 452 to form internal cavity 450 through which an antenna under test (AUT) 106 may pass. Using this configuration, each of conductive plates 460 and 462 forms a continuous feed structure (in this case a loop) that completely encircles the inserted antenna 106 in at least one plane during testing conditions to increase uniformity of the radiated feed. It will be understood that in other embodiments conductive components of a continuous feed structure may have any configuration other than a plate that is suitable for encircling and radiating a test signal to an AUT, for example, such as conductive bars (e.g., parallel oriented) that are configured to encircle and form a loop around an AUT, flat conductive straps (e.g., parallel oriented) that are configured to encircle and form a loop around an AUT, etc.

In the exemplary embodiment of FIG. 4, an optional neck segment 475 of antenna enclosure 108 may be provided as shown adjacent the insertion opening end of hood 108. Neck segment 475 may be optionally chamfered as shown to have reduced external dimension and cross sectional area relative to the remaining section of hood 108 for purposes of clearing external surfaces or structure of aircraft 102. Other optional modifications to the external shape of an antenna enclosure 108 may be provided for clearance where appropriate to meet the characteristics of a given application. Optional handling features, such as one or more handles, may be provided on one or more external surfaces of an antenna test enclosure 108 for purposes of ease of handling and installation/removal of the enclosure relative to an antenna 106.

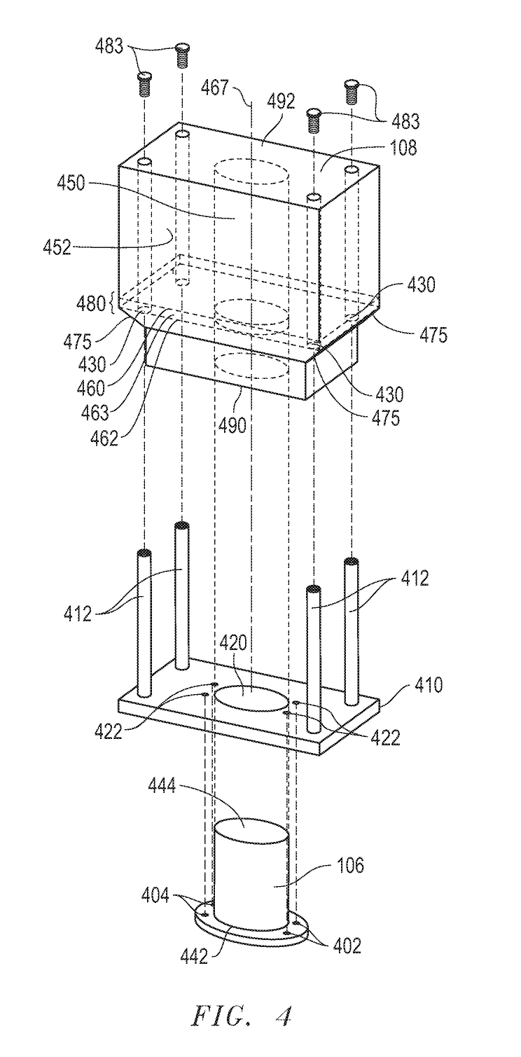

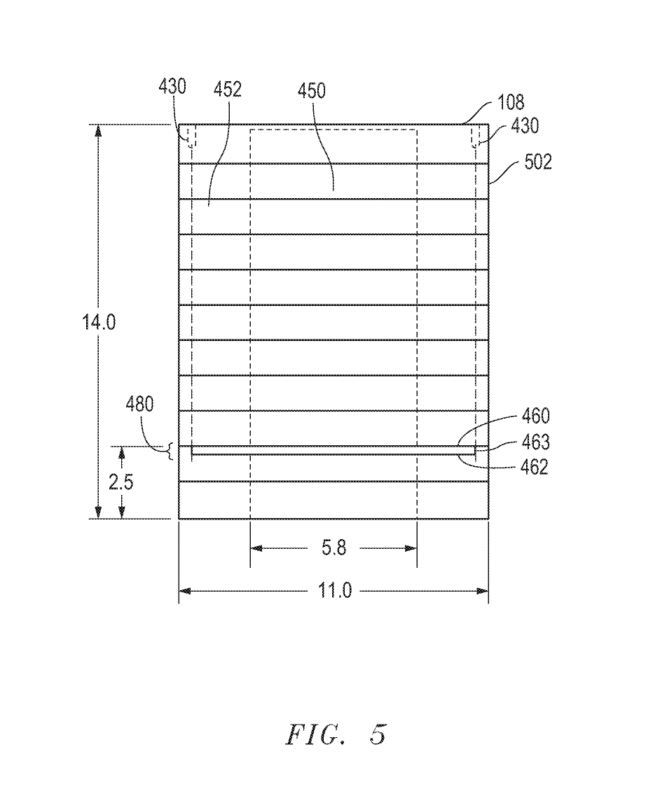

FIGS. 5 and 6 illustrate wide-side and narrow-side partial cross-sectional views of one embodiment of antenna enclosure 108, and include example dimensions (in inches) configured for a UHF frequency band DF type blade antenna, it being understood that these dimensions are exemplary only and that other dimensions are possible. Internal features of antenna hood 108 are indicated in dashed outline, including components of embedded antenna feed 480. As shown, antenna hood 108 is configured in this embodiment as a rectangular block of RF absorbing material matrix 452, an embedded antenna feed 480 and an opening on the bottom exposing a centralized cavity 450 to envelope an antenna under test (AUT) 106. In such an embodiment, RF absorber material of matrix 452 may be provide to serve two purposes: to reduce RF “ringing” of the AUT's response and to increase the isolation to the external RF environment, such as may be encountered during a ground test of an aircraft-based DF receiver system and antenna array.

In one exemplary embodiment, components of embedded antenna feed 480 may include 0.005 inch thick parallel conductive copper plates 460 and 462 that sandwich and are separated by a 0.25 inch thick high density polyethylene dielectric plate 463 that is also oriented parallel to plates 460 and 462. However, it will be understood that spacing and thickness of the components of embedded antenna feed 480 may vary based on a given application for injecting a RF test signal into a given antenna enclosure 108 to cause a response in an inserted antenna 106.

In one exemplary embodiment, RF absorbing matrix 452 may be multiple bonded (laminated) layers of RF absorbing material. One example of such a layered RF absorbing material is made of carbon-loaded phenolic honeycomb, and is available as 1.25 inch thick layers of C-RAM HCU1.25/30 dB IL per inch at 10 GHz per inch, available from Cuming Microwave Corporation. For the particular exemplary dimensions of FIGS. 5-6, eleven 1.25 inch layers of such materials may be bonded together with an adhesive such a structural epoxy adhesive. It will be understood that the embodiment of FIG. 3 is exemplary only, and that other shapes and configurations of antenna test enclosures may be provided for installation over other types and configurations of antennas, e.g., antenna enclosures including RF absorbing matrix of rubber/flexible sheet RF absorbing materials, foam sheet RF absorbing materials, ceramic sheet RF absorbing materials, etc.

Still referring to FIGS. 5 and 6, antenna hood 108 include an optional external housing 502 that surrounds or otherwise encloses RF absorber material 452 and embedded antenna feed 480. Such an external housing 502 may be selected based on providing isolation from external RF signals. In one exemplary embodiment, external housing 502 may be a metallic housing, e.g., such as a 0.020 inch thick layer of conductive nickel paint (e.g., EMI/RFI shielding spray available as Super Shield 841-340G from MG Chemicals). Outer surfaces (top and four sides) of external housing 502 may be optionally covered with a metal conductor such as aluminum.

In one exemplary embodiment, the positioning of embedded antenna feed 480 relative to the base of a blade antenna 106 received within internal cavity 450 may be optionally selected based on measured antenna receive pattern to optimize response of an inserted antenna 106 to a RF test signal injected by embedded antenna feed 480, e.g. via a respective signal injection conductor 104 previously described. In this regard, signal amplitude and phase response of a given antenna 106 (e.g., UHF Blade Antenna) to an injected signal may be measured versus relative position of embedded antenna feed 480 to determine the position relative to the inserted antenna 106 where the strongest and smoothest (or flattest) trend in the amplitude test signal response is achieved from antenna 106. This may be accomplished, for example, by moving the position of embedded antenna feed 480 between the proximal (base) end 442 and distal (tip) end 444 of the antenna 106, and by measuring and comparing signal amplitude and phase response of a given antenna 106 to a signal injected at multiple different positions of embedded antenna feed 480 between the proximal (base) end 442 and distal (tip) end 444 of the antenna 106, e.g., by comparing the measured antenna response to a RF test signal injected by embedded antenna feed 480 at a first position that is closer to the proximal end 442 of antenna 106 to the measured antenna response to a RF test signal injected by the embedded antenna feed 480 at a second position that is farther from the proximal end 442 of antenna 106 than is the first position. This process may be repeated for as many different positions of antenna feed 480 relative to antenna 106 as desired or appropriate for a given application. In this regard, a flat and smooth amplitude response is indicative of phase response that will be substantially free of, or that will minimize, sharp phase discontinuities when measuring the phase matching between antennas.

Thus, in one exemplary embodiment an embedded antenna feed 480 may be positioned within the internal cavity 450 of an antenna test enclosure 104 based on a measured antenna receive amplitude and phase response so that the RF feed is positioned at a location selected to maximize a flat amplitude response across the frequency band and yield a phase response that minimizes phase ripple and discontinuities of the antenna 106 to the RF test signal when the antenna 106 is positioned within the antenna test enclosure 104. The optimum such determined position for one exemplary embodiment is shown by the dimensions noted in FIGS. 5 and 6, although it will be understood that an optimum antenna position will vary with different types of antenna 106, and that selection and use of such an optimum position is optional only. Moreover, once an optimum position is determined for a given configuration of AUT 106, multiple antenna hoods 108 may be configured in a similar manner for testing of other similarly-configured antennas 106.

FIGS. 5 and 6 also illustrate a signal injection conductor 104 coupled to provide a RF test signal to embedded antenna feed 480 for testing. In this exemplary embodiment, signal conductor 104 is a coaxial cable (e.g., Storm Flex 141 coaxial cable from Teledyne) that extends from outside hood 108 across the exterior surface (i.e., top surface relative to the orientation of FIGS. 5 and 6) of conductive plate 460 of embedded antenna feed 480. In this exemplary embodiment, the outer conductor 710 of coaxial cable 104 is electrically coupled to conductive plate 460 (e.g., by soldering) to form a ground plane, and the center conductor 712 is bent to extend through the antenna opening 450 defined in embedded antenna feed 480 and electrically coupled to conductive plate 462 (e.g., by soldering) to form the feed, it being understood that center conductor 712 may be alternatively coupled to form the ground plane, and outer conductor 710 may be alternatively coupled to form the feed.

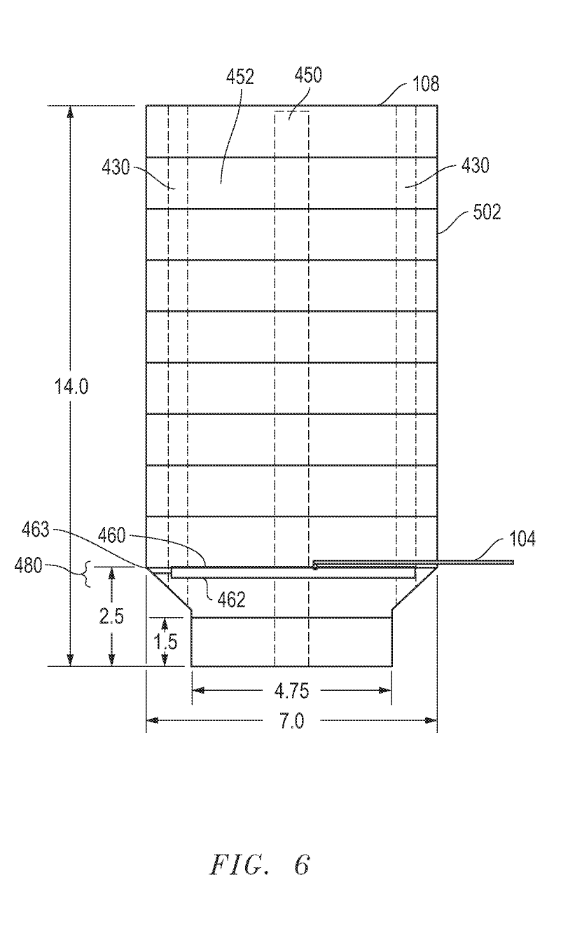

FIG. 7 is a top view of one exemplary embodiment of a structure of an assembled antenna feed 480, showing a FR4 fiberglass board having conductive copper laminated layers (e.g., 0.005 inch thick copper layers) attached with pressure sensitive adhesive (PSA) on either side to form conductive upper plate 460. Conductive lower plate 462 (not visible in FIG. 7) may be of similar structure, and conductive plates 460 and 462 sandwich dielectric plate 463, which may be high density polyethylene (HDPE) or other suitable dielectric material, e.g., of about 0.25 inch thickness or any other suitable thickness to fit the given application.

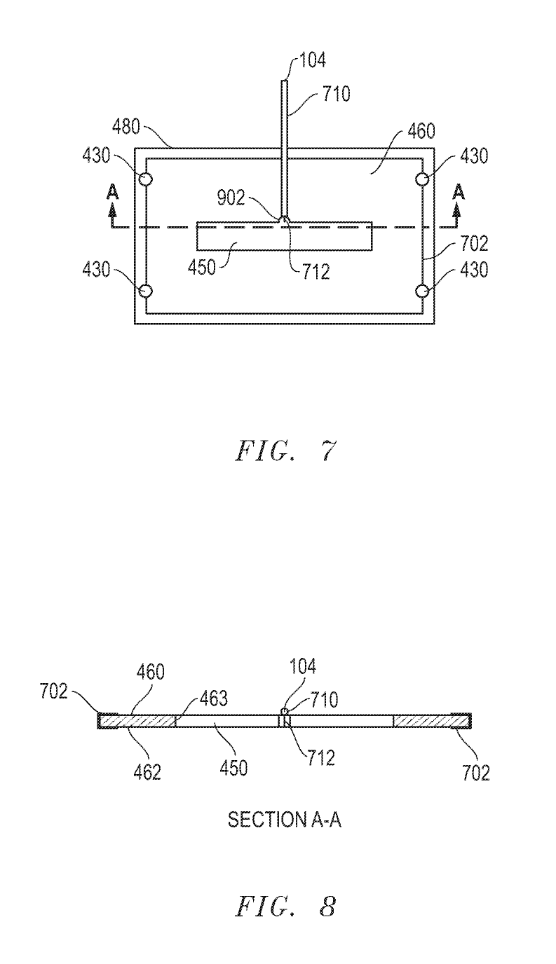

In the embodiment of FIG. 7, a layer of conductive tape 702 (e.g., 1 inch wide copper tape) may be wrapped around outer edges of the structure of antenna feed 480 for purpose of electrically connecting the upper and lower plates 460 and 462 around the center dielectric plate 463 as shown. Optional alignment and securing openings 430 may be shown for receiving guide pins 412 in a manner as previously described, and may be about 0.38 inch diameter in one exemplary embodiment. Also, as previously described, the outer conductor 710 of coaxial cable 104 is electrically coupled to upper conductive plate 460, and the center conductor 712 is bent down to extend through the antenna opening 450 defined in embedded antenna feed 480 and electrically coupled (e.g. soldered) to lower conductive plate 462. FIG. 8 illustrates a view of section A-A of FIG. 7. In this exemplary embodiment, cavity opening 450 may have dimensions of 5.80 inches by 0.80 inches, it being understood that dimensions of cavity opening 450 may vary to fit the dimensions of the particular type of antenna employed for a given application.

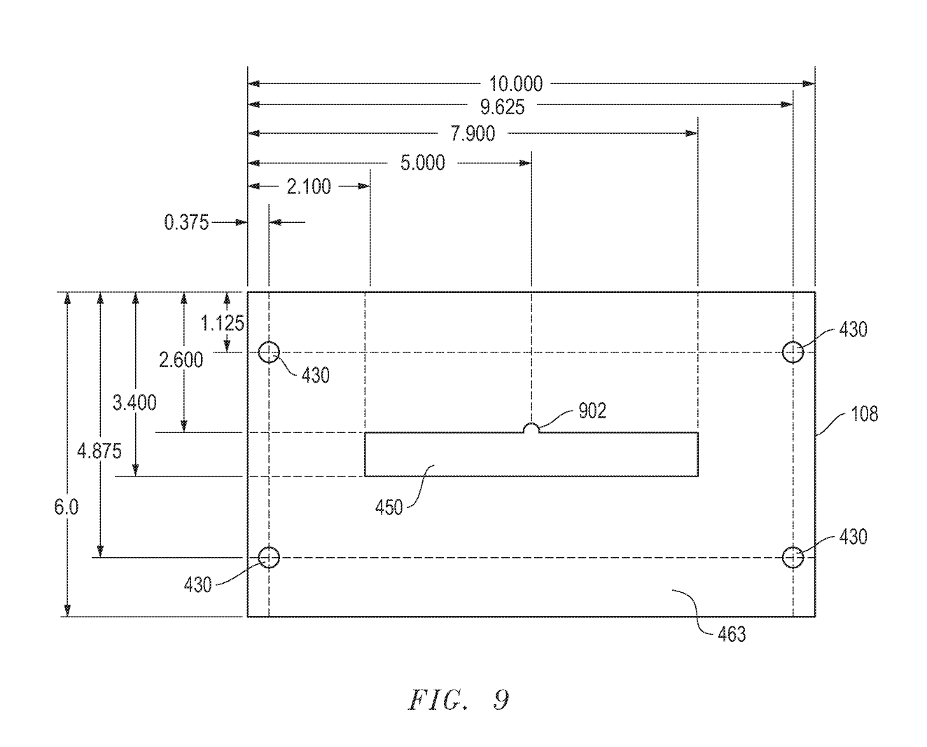

FIG. 9 illustrates a top view of dielectric plate 463, showing example dimensions (in inches) for one exemplary embodiment, it being understood that dimensions and shape may vary to fit the particular characteristics of a given application and type of antenna. FIG. 9 illustrates a half-cylinder shaped clearance recess 902 (e.g., 0.25 inch diameter) defined in plate 463 for receiving and recessing the center conductor 712 of coaxial cable 104 of FIGS. 7 and 8.

As configured according to the above, each antenna hood 108 creates an anechoic chamber environment for testing of an antenna 106. In one embodiment, phase and amplitude measurements of an array of multiple direction finding antenna elements 106 may be performed by using multiple hoods 108. In this regard, each given one of the multiple hoods 108 may be positioned to cover a given one of the multiple respective antennas 106 in the array to allow for simultaneous phase matched test signals to be induced into all antennas 106 in the array. Previously described FIG. 1 illustrates such an installation of multiple hoods 108 over multiple antennas 106 for testing, and FIG. 4 illustrates alignment of a given antenna hood 108 with a given antenna 106.

While the invention may be adaptable to various modifications and alternative forms, specific examples and exemplary embodiments have been shown by way of example and described herein. However, it should be understood that the invention is not intended to be limited to the particular forms disclosed. Rather, the invention is to cover all modifications, equivalents, and alternatives falling within the spirit and scope of the systems and methods described herein. Moreover, the different aspects of the disclosed systems and methods may be utilized in various combinations and/or independently. Thus the invention is not limited to only those combinations shown herein, but rather may include other combinations.

What is claimed is:

1. A method for testing one or more radio frequency antennas, the method comprising:
providing one or more antennas and a corresponding RF signal path coupled to each of the antennas;
providing one or more antenna test enclosures, each of the antenna test enclosures corresponding to one of the antennas and being configured to receive one of the antennas when positioned therein, each of the antenna test enclosures comprising a RF feed configured to radiate a RF test signal, the RF feed being configured as a continuous feed structure that completely encircles the antenna in at least one plane when the antenna is positioned within the antenna test enclosure;
positioning each of the one or more antennas within a corresponding one of the one or more antenna test enclosures so that the continuous feed structure of the RF feed completely encircles the antenna in at least one plane;
providing a RF test signal to each given one of the one or more antenna test enclosures to cause the RF feed of the given antenna test enclosures to radiate the RF test signal to a corresponding one of the one or more antennas; and
measuring the response to the RF test signal provided to each of the one or more antenna antennas and the RF signal path corresponding to each of the one or more antennas.

2. The method of claim 1, where the one or more antennas comprise multiple antennas; where the one or more antenna test enclosures comprise multiple test enclosures corresponding to the multiple antennas; and where the method further comprises:
providing a RF test signal to each given one of the multiple antenna test enclosures to cause the RF feed of the given antenna test enclosure to radiate the RF test signal to a corresponding one of the multiple antennas; and
measuring the response to the RF test signal provided to each of the multiple antennas and the RF signal path corresponding to each of the multiple antennas.

3. The method of claim 2, where the multiple antennas comprise multiple antennas of a direction finding (DF) antenna array; and where the method further comprises:
simultaneously providing each of the RF test signals to each of the multiple antenna test enclosures with a common phase;
measuring the response to each of the RF test signals simultaneously provided to each of the multiple antennas and the RF signal path corresponding to each of the multiple antennas; and
comparing the measured response of each of the multiple antennas and its corresponding RF signal path to each other of the multiple antennas and its corresponding RF signal path to determine any offset error in detected phase between the multiple antennas and their corresponding signal paths.

4. The method of claim 1, further comprising comparing the absolute value of at least one of phase or amplitude of the provided RF test signal to each of the one or more antenna test enclosures to a measured response of a corresponding one of the one or more antennas and its corresponding RF signal path to determine any error in at least one of amplitude or phase measured by the corresponding one of the one or more antennas and its corresponding RF signal path.

5. The method of claim 1, where each given one of the one or more antenna test enclosures further comprises:
a matrix of RF absorber material, the RF feed being embedded in the matrix of RF absorber material;
an internal cavity defined within the matrix and the embedded RF feed, the internal cavity defined to extend through the matrix and the embedded RF feed and being shaped and dimensioned to surround a corresponding antenna when the corresponding antenna is positioned within the given antenna test enclosure;
where the embedded RF feed is configured as a continuous feed structure that completely encircles the corresponding antenna in at least one plane when the antenna is positioned within the given antenna test enclosure.

6. The method of claim 5, where the matrix of RF absorbing material is configured to create an anechoic chamber within the internal cavity for RF testing the corresponding antenna with an RF test signal when the antenna is positioned within the internal cavity of the given antenna test enclosure; the internal cavity being configured to allow for RF testing of the corresponding antenna within the internal cavity with substantially no RF energy ringing occurring within the internal cavity and with substantially no interference from signal noise from the environment external to the given antenna test enclosure.

7. The method of claim 1, where the RF feed of each given one of the one or more antenna test enclosures comprises at least two conductive plates separated by a dielectric material, the conductive plates being oriented parallel to each other for radiating the RF test signal with one of the plates configured as a ground plane and the other of the plates being configured as a signal feed; and where an opening is defined to extend through the conductive plates and dielectric material of the RF feed to receive and encircle a corresponding antenna when the corresponding antenna is positioned within the given antenna test enclosure.

8. The method of claim 1, where one of the RF feeds is positioned within each given one of the antenna test enclosures based on a measured antenna receive pattern so that the RF feed is positioned at a location selected to maximize a signal response of a corresponding antenna to the RF test signal when the corresponding antenna is positioned within the given antenna test enclosure.

9. A system for testing one or more radio frequency antennas and a corresponding RF signal path coupled to each of the antennas, the system comprising:
one or more antenna test enclosures, each of the antenna test enclosures corresponding to one of the antennas and being configured to receive one of the antennas when positioned therein, each of the antenna test enclosures comprising a RF feed configured to radiate a RF test signal, the RF feed being configured as a continuous feed structure that completely encircles the antenna in at least one plane when the antenna is positioned within the antenna test enclosure; and
test circuitry configured to provide a RF test signal to each given one of the one or more antenna test enclosures to cause the RF feed of the given antenna test enclosures to radiate the RF test signal to a corresponding one of the one or more antennas.

10. The system of claim 9, where the test circuitry is configured to provide a RF test signal to each given one of the one or more antenna test enclosures so as to cause the RF feed of the given antenna test enclosure to radiate the RF test signal to a corresponding one of the one or more antennas to cause the corresponding antenna to produce a signal response that is measurable to verify one or more electrical properties of the corresponding antenna and signal path coupled thereto.

11. The system of claim 9, where the test circuitry is configured to:
simultaneously provide each of the RF test signals to each given one of the one or more antenna test enclosures with a common phase so as to cause the RF feed of the given antenna test enclosure to radiate the RF test signal to a corresponding one of the one or more antennas to cause the corresponding antenna to produce a signal response;
measure the response to each of the RF test signals simultaneously provided to each of the multiple antennas and the RF signal path corresponding to each of the multiple antennas; and
verify one or more electrical properties of the corresponding antenna and signal path coupled thereto by comparing the absolute value of at least one of phase or amplitude of the provided RF test signal to each of the one or more antenna test enclosures to a measured response of a corresponding one of the one or more antennas and its corresponding RF signal path to determine any error in at least one of amplitude or phase measured by the corresponding one of the one or more antennas and its corresponding RF signal path.

12. The system of claim 9, where the one or more antennas comprise multiple antennas; where the one or more antenna test enclosures comprise multiple test enclosures corresponding to the multiple antennas; and where the test circuitry is configured to provide a RF test signal to each given one of the multiple antenna test enclosures so as to cause the RF feed of the given antenna test enclosure to radiate the RF test signal to a corresponding one of the multiple antennas to cause the corresponding antenna to produce a signal response that is measurable to verify one or more electrical properties of the corresponding antenna and signal path coupled thereto.

13. The system of claim 12, where the multiple antennas comprise multiple antennas of a direction finding (DF) antenna array; and where the test circuitry is configured to:
simultaneously provide each of the RF test signals to each given one of the multiple antenna test enclosures with a common phase so as to cause the RF feed of the given antenna test enclosure to radiate the RF test signal to a corresponding one of the multiple antennas to cause the corresponding antenna to produce a signal response,
measure the response to each of the RF test signals simultaneously provided to each of the multiple antennas and the RF signal path corresponding to each of the multiple antennas, and
verify one or more electrical properties of the multiple antennas and signal path coupled thereto by comparing the measured response of each of the multiple antennas and its corresponding RF signal path to each other of the multiple antennas and its corresponding RF signal path to determine any offset error in detected phase between the multiple antennas and their corresponding signal paths.

14. The system of claim 9, where each given one of the one or more antenna test enclosures further comprises:
a matrix of RF absorber material, the RF feed being embedded in the matrix of RF absorber material;
an internal cavity defined within the matrix and the embedded RF feed, the internal cavity defined to extend through the matrix and the embedded RF feed and being shaped and dimensioned to surround a corresponding antenna when the corresponding antenna is positioned within the given antenna test enclosure;
where the embedded RF feed is configured as a continuous feed structure that completely encircles the corresponding antenna in at least one plane when the antenna is positioned within the given antenna test enclosure.

15. The system of claim 9, where one of the RF feeds is positioned within each given one of the antenna test enclosures based on a measured antenna receive pattern so that the RF feed is positioned at a location selected to maximize a signal response of a corresponding antenna to the RF test signal when the corresponding antenna is positioned within the given antenna test enclosure.

16. An antenna test enclosure configured to receive a radio frequency antenna when positioned therein, the antenna test enclosure comprising a RF feed configured to radiate a RF test signal, the RF feed being configured as a continuous feed structure that completely encircles the antenna in at least one plane when the antenna is positioned within the antenna test enclosure.

17. The antenna test enclosure of claim 16, further comprising:
a matrix of RF absorber material, the RF feed being embedded in the matrix of RF absorber material; and
an internal cavity defined within the matrix and the embedded RF feed, the internal cavity defined to extend through the matrix and the embedded RF feed and being shaped and dimensioned to surround the antenna when the antenna is positioned within the antenna test enclosure;
where the embedded RF feed is configured as a continuous feed structure that completely encircles the antenna in at least one plane when the antenna is positioned within the antenna test enclosure.

18. The antenna test enclosure of claim 17, where the antenna test enclosure is configured to receive a antenna having a proximal end and an opposite distal end; and where the internal cavity is defined with a shape and dimensions complementary to the exterior dimensions of the antenna such that the antenna is surrounded on at least all sides between the proximal and distal ends of the antenna by the RF absorbing material matrix or embedded RF feed when the antenna is positioned within the antenna test enclosure.

19. The antenna test enclosure of claim 17, where the antenna test enclosure is configured to receive a antenna having a proximal end and an opposite distal end; where the antenna test enclosure comprises a proximal end and a distal end, the internal cavity extending toward the distal end of the antenna test enclosure from an opening defined in the proximal end of the antenna test enclosure; and where the opening in the proximal end of the antenna test enclosure is configured for receiving the distal end of the antenna by insertion to allow the antenna to be positioned within the internal cavity of the antenna test enclosure with the proximal end of the antenna being disposed adjacent the proximal end of the test enclosure, and the distal end of the antenna being disposed adjacent the distal end of the test enclosure.

20. The antenna test enclosure of claim 17, where the matrix of RF absorbing material is configured to create an anechoic chamber within the internal cavity for RF testing the antenna with an RF test signal when the antenna is positioned within the internal cavity; the internal cavity being configured to allow for RF testing of the antenna within the internal cavity with substantially no RF energy ringing occurring within the internal cavity and with substantially no interference from signal noise from the environment external to the antenna test enclosure.

21. The antenna test enclosure of claim 17, further comprising an external housing at least partially surrounding the RF absorber material, the external housing at least one of comprising or being coated with one or more RF shielding materials.

22. The antenna test enclosure of claim 16, where the RF feed comprises at least two conductive plates separated by a dielectric material, the conductive plates being oriented parallel to each other for radiating the RF test signal with one of the plates configured as a ground plane and the other of the plates being configured as a signal feed; and where an opening is defined to extend through the conductive plates and dielectric material of the RF feed to receive and encircle the antenna when the antenna is positioned within the antenna test enclosure.

23. The antenna test enclosure of claim 16, where the RF feed is positioned within the antenna test enclosure based on a measured antenna receive amplitude and phase response so that the RF feed is positioned at a location selected to maximize a flat amplitude response across the frequency band and yield a phase response that minimizes phase ripple and discontinuities of the antenna to the RF test signal when the antenna is positioned within the antenna test enclosure.

24. The antenna test enclosure of claim 16, configured as an antenna test enclosure system, where the antenna test enclosure system further comprises an alignment plate device separable from the antenna test enclosure, the alignment plate device having an antenna opening defined therein that is dimensioned to fit over and be secured in relation to an antenna between a base of the antenna and the antenna test enclosure, and the alignment plate device also having one or more guide members configured and dimensioned to be received in one or more corresponding securing openings defined in a portion of the antenna test enclosure to align and secure the antenna test enclosure in relation to the antenna.
